(19) United States
(12) Patent Application Publication
(10) Pub. No.: US 2008/0089143 A1
(43) Pub. Date: Apr. 17, 2008

(54) Voltage monitoring device in semiconductor memory device

(75) Inventor: Chang-Ho Do, Kyoungki-do (KR)

Correspondence Address: BLAKELY SOKOLOFF TAYLOR & ZAFMAN, 1279 OAKMEAD PARKWAY, SUNNYVALE, CA, 94085-4040, US

(73) Assignee: Hynix Semiconductor Inc.

(21) Appl. No.: 11/647,773

(22) Filed: Dec. 28, 2006

(30) Foreign Application Priority Data
Sep. 21, 2006 (KR) 2006-0091625

(51) Int. Cl. G11C 5/14

(52) U.S. Cl. 365/189.09

(57) ABSTRACT

An apparatus or method for monitoring an internal power voltage and generating a digital signal based on a monitored result for use in a semiconductor device includes a conversion device for converting a difference between an internal power voltage and a reference power voltage into a digital signal and an output device for transmitting the digital signal in response to a test mode signal.

### CROSS-REFERENCE TO RELATED APPLICATIONS

The present invention claims priority of Korean patent application number 10-2006-0091625, filed on Sep. 21, 2006, which is incorporated by reference in its entirety.

### BACKGROUND OF THE INVENTION

The present invention relates to a design technique for semiconductor device; and, more particularly, to an apparatus and method for monitoring an internal voltage in a semiconductor memory device.

Generally, in a semiconductor memory device, plural internal power voltages, each having different voltage levels, are generated and supplied to the plural internal units throughout inner wires for performing data access or data storage. Herein, the inner wires are constructed like a net for preventing the internal power voltages from dropping and transmitting the internal power voltages having a uniform level to the internal units respectively.

However, although the inner wires are formed like a net, a descent of the internal power voltages occurs owing to resistances of the inner wires when currents flow throughout the inner wires. According to operations or conditions, a small uA to mA amount of current flows in the semiconductor memory device. As a result, each internal power voltage does not maintain a desirable voltage level but goes down or fluctuates because of the resistances of the inner wires. This descent phenomenon of the internal power voltage appears diversely in response to a total resistance of inner wire from an internal power supply to a target internal unit or a current consumption of the target internal unit.

A state that the internal power voltage goes down or fluctuates is similar to that of an analog signal of which voltage or current level always alters over or below a desirable reference. This characteristic of the internal power voltage in the semiconductor memory device that should sense and amplify a potential of minute unit cell for reading a data can cause unstable operations such as a data loss or a malfunction. The unstable operations are representative grounds for being able to fabricate the semiconductor memory device. To over come the above described problem, the semiconductor memory device is embodied with an apparatus for monitoring a level of internal power voltage.

FIG. 1 illustrates a block diagram of a conventional internal power monitoring device.

As shown, the conventional internal power monitoring device includes plural monitoring pads for checking plural internal power voltages. For monitoring a level of the plural internal power voltages, a probe tip, included in a probe unit, for delivering a level of internal power voltage into an oscilloscope or a tester for outputting an average of internal power voltage levels during a predetermined time is further required.

However, a conventional method using the probe tip and the oscilloscope is difficult for checking the internal power voltage accurately. The internal power voltage is not fully swung like a digital signal transited between a logic high level to a logic low level, but varies in a range of a few mV, e.g., several tens mV to several hundreds mV. Because of test conditions such as a capacity of an oscilloscope and noise of a probe tip and connected wires, the internal power voltage can be distorted. Accordingly, even though a level detector has good performances, a level of the internal power voltage cannot be recognized accurately.

Another conventional method using the tester is also not accurate. The tester receives the average level of the internal power voltage, not a real-time varied level of the internal power voltage. By using the average level of the internal power voltage, the tester cannot understand a change of the internal power voltage and an operational state of each functional unit included in the semiconductor device. Particularly, in the conventional methods, a package of the semiconductor device does not have a pin or a ball connected to a monitoring pad for measuring the internal power voltage. Accordingly, after the semiconductor device is packaged, the internal power voltage cannot be checked.

### SUMMARY OF THE INVENTION

Embodiments of the present invention are directed to provide an apparatus and a method for monitoring an internal power voltage and generating a digital signal based on a monitored result.

In accordance with an aspect of the present invention, there is provided an apparatus for monitoring an internal power voltage for use in a semiconductor device, including a conversion device for converting a difference between an internal power voltage and a reference power voltage into a digital signal and an output device for transmitting the digital signal in response to a test mode signal.

In accordance with another aspect of the present invention, there is provided an apparatus for monitoring an internal power voltage used inside a semiconductor memory device, including a voltage input device for recognizing a level of a power voltage to generate a signal corresponding to the sensed level and an output device for transmitting the signal in response to a test mode signal.

In accordance with a further another aspect of the present invention, there is provided a method for monitoring an internal power voltage for use in a semiconductor device, including converting a difference between an internal power voltage and a reference power voltage into a digital signal and transmitting the digital signal in response to a test mode signal.

In accordance with another aspect of the present invention, there is provided a method for monitoring an internal power voltage used inside a semiconductor memory device, including recognizing a level of a power voltage to generate a signal corresponding to the sensed level and transmitting the signal in response to a test mode signal.

### BRIEF DESCRIPTION OF THE DRAWINGS

FIG. 1 illustrates a block diagram of a conventional internal power monitoring device.

FIG. 2 illustrates a block diagram of an internal power monitoring device in accordance with an embodiment of the present invention.

FIGS. 3A and 3B illustrate schematic circuit diagrams of first and second dividers shown in FIG. 2 according to embodiments of the present invention.

FIG. 4 illustrates a schematic circuit diagram of a partial of test mode decision block shown in FIG. 2.

FIG. 5 illustrates a schematic circuit diagram of a comparator and a buffering unit shown in FIG. 2.

FIGS. 6A to 6C illustrate schematic circuit diagrams of multiplexing unit shown in FIG. 2 according to embodiments of the present invention.

FIGS. 7A and 7B illustrates timing diagrams describing an operation of the internal power monitoring device shown in FIG. 2.

FIG. 8 illustrates a timing diagram depicting a digitalization of internal power voltage on a basis of plural reference power voltages.

FIG. 9 illustrates a block diagram of an internal power monitoring device in accordance with another embodiment of the present invention.

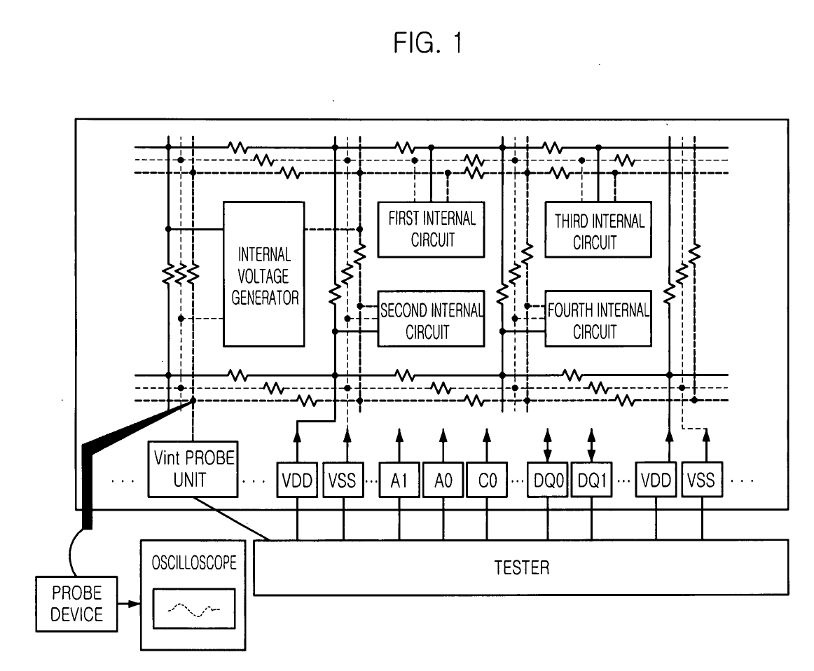

### DESCRIPTION OF SPECIFIC EMBODIMENTS

Hereinafter, a semiconductor device such as a memory device, e.g., DRAM and SRAM, in accordance with specific embodiments of the present invention will be described in detail with reference to the accompanying drawings.

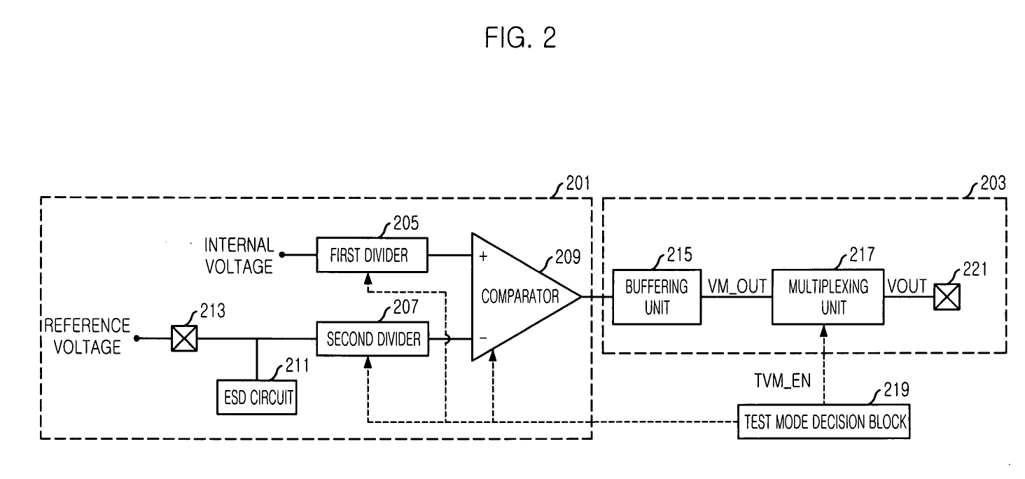

FIG. 2 illustrates a block diagram of an internal power monitoring device in accordance with an embodiment of the present invention.

As shown, the internal power monitoring device includes a conversion device 201 for converting a difference between an internal power voltage and a reference power voltage into a digital signal and an output device 203 for transmitting the digital signal in response to a test mode signal.

The conversion device 201 includes a first divider 205 for dividing a level of the internal power voltage by a predetermined ratio, a second divider 207 for dividing a level of the reference power voltage by the predetermined ratio, and a comparison unit 209 for comparing outputs of the first and second dividers 205 and 207 to generate the digital signal.

The conversion device 201 further includes an input pad 213 supplied with the reference power voltage and an electrostatic discharge (ESD) unit 211 coupled between the input pad 213 and the second divider 207.

The output device 203 includes a buffering unit 215 for buffering the digital signal outputted from the comparison unit 209 to generate a buffered digital signal VM_OUT and a multiplexing unit 217 for transmitting the buffered digital signal VM_OUT to a pad 221 in response to a test enable signal TVM_EM included in the test mode signal.

Herein, the pad 221 includes an address pad for address input/output, a data pad for data input/output, and a monitoring pad which is unfit for data access. The monitoring pad is a special pad only used for checking a level of the internal power voltage.

The internal power monitoring device can use a general pad, e.g., the pad 221. Because the general pad widely used for operations of the semiconductor device is coupled to a pin or a ball of a package, the internal power voltage inside the semiconductor device can be measured after the semiconductor device is packaged.

The test enable signal TVM_EM is generated from the test mode decision block 219. The test mode decision block 219 determines an operational mode of the semiconductor device and generates the test enable signal TVM_EN for controlling the conversion device 201, the output device 203, or both.

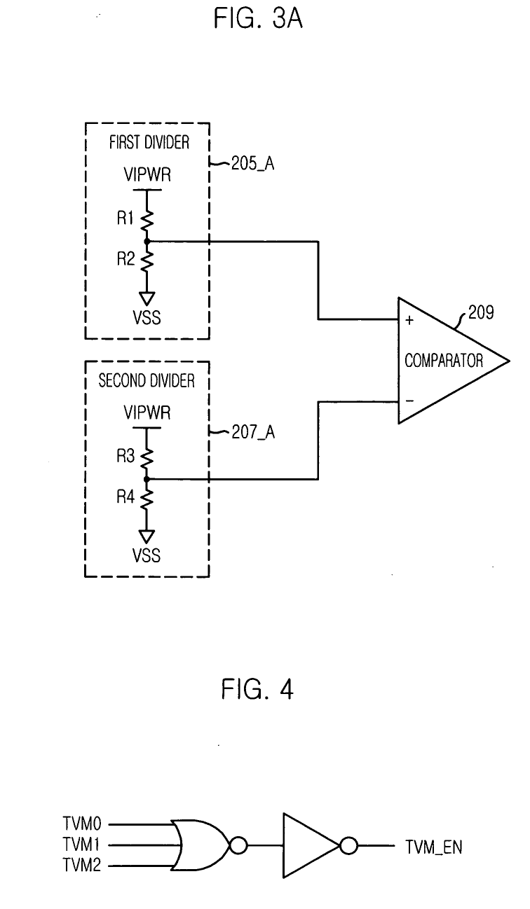

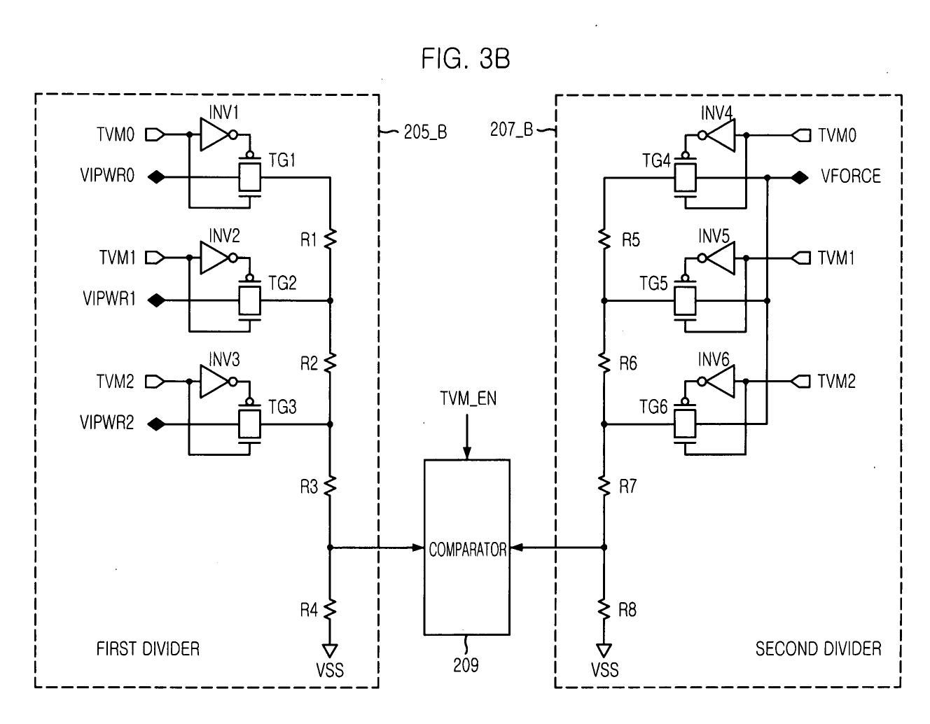

FIGS. 3A and 3B illustrate schematic circuit diagrams of first dividers 205_A and 205_B and second dividers 207_A and 207_B shown in FIG. 2 according to embodiments of the present invention.

Referring to FIG. 3A, the first divider 205_A includes two resistors R1 and R2 connected in series and divides a voltage level of inputted internal power voltage VIPWR by a predetermined ratio determined based on resistances of the two resistors R1 and R2.

Likewise, the second divider 207_A includes two resistors R3 and R4 connected in series and divides a voltage level of inputted reference power voltage VFORCE by a predetermined ratio determined based on resistances of the two resistors R3 and R4.

Outputs of the first and second divider 205_A and 207_A are inputs of the comparator 209. If the reference power voltage VFORCE is inputted through the input pad 213 after being adjusted by another device, the second divider 207_A can be omitted in the conversion device 201.

Referring to FIG. 3B, the first and second dividers 205_B and 207_B supports an operation for monitoring plural internal power voltages VIPWR0, VIPWR1, and VIPWR2.

The first divider 205_B includes plural transmission gates TG1, TG2, and TG3 for transmitting the plural internal power voltages VIPWR0, VIPWR1, and VIPWR2 in response to test selection signals TVM0, TVM1, and TVM2 and plural resistors R5, R6, R7, and R8 for dividing transmitted internal power voltage by a predetermined resistance ratio corresponding to resistors coupled between the transmitted internal power voltage and a ground voltage VSS. Herein, the test selection signals TVM0, TVM1, and TVM2 are also included in the test mode signal outputted from the test mode decision block 219, like the test enable signal TVM_EN.

In FIG. 3, there are only three transmission gates corresponding to the three internal power voltages VIPWR0, VIPWR1, and VIPWR2. However, the number of the transmission gates and resistors are changed according to how many internal power voltages are monitored.

The second divider 207_B is similar to the first divider 205_B in a view of its inner structure. The second divider 207_B includes plural transmission gates TG4, TG5, and TG6 for transmitting reference power voltages VFORCE0, VFORCE1, and VFORCE2 in response to test selection signals TVM0, TVM1, and TVM2 and plural resistors R9, R10, R11, and R12 for dividing transmitted internal power voltage by a predetermined resistance ratio corresponding to resistors coupled between the transmitted internal power voltage and a ground voltage. Herein, each of the reference power voltages VFORCE0, VFORCE1, and VFORCE2 correspond to each monitored internal power voltage inputted to the first divider 205_B. Similar to the second divider 207_A, if the reference power voltage VFORCE is inputted through the input pad 213 after being adjusted by another device, the second divider 207_B can be omitted in the conversion device 201.

FIG. 4 illustrates a schematic circuit diagram of partial of test mode decision block 209 shown in FIG. 2. Particularly, FIG. 4 describes how to generate the test enable signal TVM_EN based on the test selection signals TVM0, TVM1, and TVM2.

Herein, the test selection signals TVM0, TVM1, and TVM2 controlling transmission gates included in the first and second dividers 205_B and 207_B are inputted from external device or generated based on instructions of a semiconductor device.

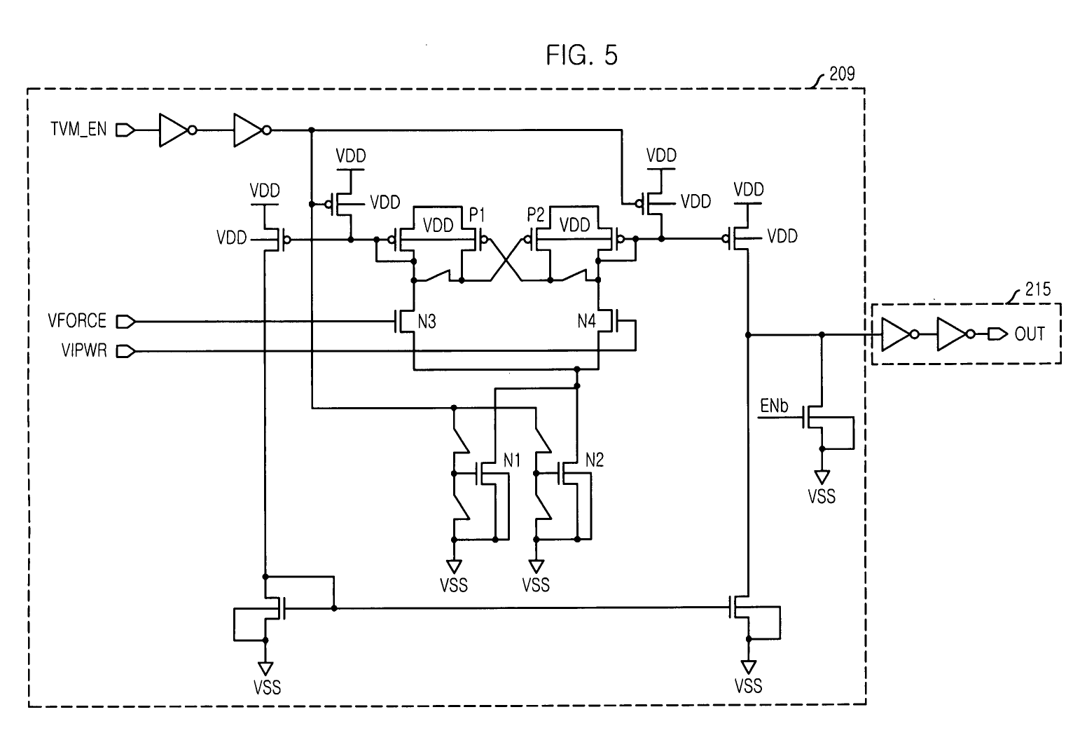

FIG. 5 illustrates a schematic circuit diagram of the comparator 209 and the buffering unit 215 shown in FIG. 2.

As shown, the comparator 209 includes a differential amplifier and a control unit. The differential amplifier includes PMOS transistors P1 and P2 forming a current mirror and NMOS transistors N3 and N4 receiving the internal power voltage VIPWR and the reference power voltage VFORCE. Other NMOS transistors N1 and N2 are served as a current source turned on or off in response to the test enable signal TVM_EN. For the residue, the control unit including other elements, PMOS and NMOS transistors, is supplementary for stably controlling the differential amplifier in response to the test enable signal TVM_EN.

The comparator 209 compares the internal power voltage VIPWR with the reference power voltage VFORCE and digitalizes a level difference of internal power voltage VIPWR on basis of the reference power voltage VFORCE.

Further, the buffering unit 215 included in the output device 203 is constituted with even number of inverters INV2 and INV3 connected in series, for buffering an output of the comparator 209 to output a transmitted digital signal VM_OUT.

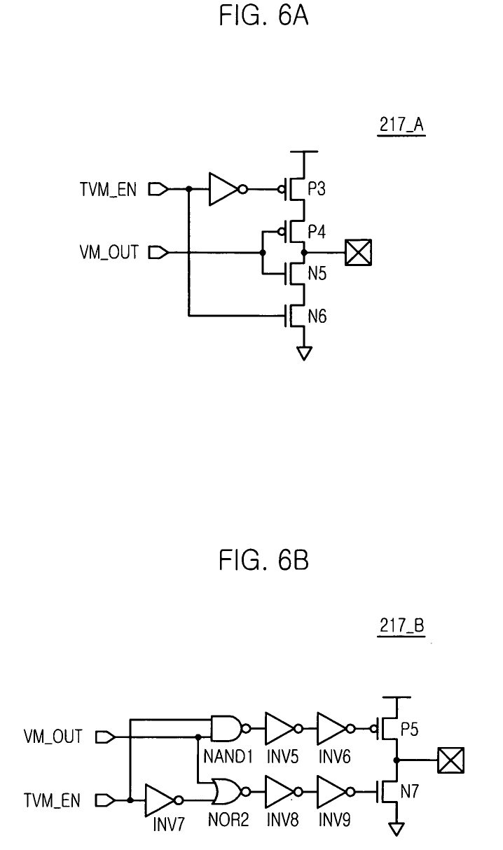

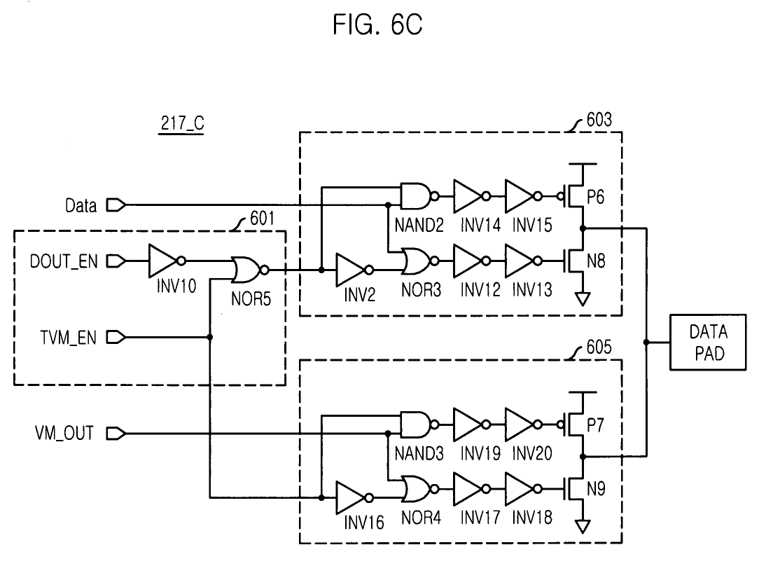

FIGS. 6A to 6C illustrate schematic circuit diagrams of multiplexing units 217_A, 217_B, and 217C shown in FIG. 2 according to embodiments of the present invention.

Referring to FIG. 6A, the multiplexing unit 217_A includes a fourth inverter INV4, third and fourth PMOS transistors P3 and P4, and fifth and sixth NMOS transistors N5 and N6. The fourth PMOS transistor P4 and the fifth NMOS transistors N5 are for delivering the transmitted digital signal VM_OUT into the pad 221, and the third PMOS transistor P3 and the sixth NMOS transistor N6 are turned on or off in response to the test enable signal TVM_EN. The fourth inverter INV4 inverts the test enable signal TVM_EN to output an inverse one to the third PMOS transistor P3.

Above described multiplexing unit 217_A delivers the transmitted digital signal into the pad 221 in response to the test enable signal TVM_EN.

Referring to FIG. 6B, the multiplexing unit 217_B includes a seventh inverter for inverting the test enable signal TVM_EN, a first logic NAND gate NAND1 for performing a logic NAND operation to the transmitted digital signal VM_OUT and the test enable signal TVM_EN, a second logic NOR gate NOR2 for performing a logic NOR operation to the transmitted digital signal TVM_EN and an output from the seventh inverter INV7, a fifth PMOS transistor P5 of which gate is coupled to the first logic NAND gate NAND1, and a seventh NMOS transistor N7 of which gate is coupled to the second logic NOR gate NOR2, wherein a signal supplied on a node between the fifth PMOS and seventh NMOS transistors P5 and N7 is outputted as the data to the pad 221.

Further, an even number of inverters, i.e., INV5 and INV6 or INV8 and INV9, are located between the first logic NAND gate NAND1 and the fifth PMOS transistor P5 and between the second logic NOR gate NOR2 and the seventh NMOS transistor N7.

The multiplexing units 217_A and 217_B shown in FIGS. 6A and 6B delivers the digital signal into the pad 221 which is only used for monitoring the internal power voltage, not performing another operation such as data access. Though the multiplexing unit 217_B shown in FIG. 6B is similar to the multiplexing unit 217_A shown in FIG. 6A in a view of function, the multiplexing unit 217_B has different elements and structures.

In contrast with the multiplexing units 217_A and 217_B, the multiplexing unit 217_C shown in FIG. 6C is coupled to a data pad served as the pad 221. Herein, the data pad is used for performing not only a monitoring operation but also a data access operation. That is, the multiplexing unit 217_C delivers the transmitted digital signal VM_OUT into the data pad.

For using a general pad such as the data pad for monitoring the internal power voltage, the multiplexing unit 2017_C includes a data output block 603 for delivering data to the data pad, a digital signal output block 605 for delivering the transmitted digital signal TVM_EN to the data pad in response to the test enable signal TVM_EN, and an output controller 601 for controlling the data output block 603 in response to the test enable signal TVM_EN and a data output enable signal DOUT_EN.

The output controller 601 includes an inverter INV10 for inverting the data output enable signal DOUT_EN, and a logic NOR gate NOR5 for performing a logic NOR operation to the test enable signal TVM_EN and output of the inverter INV10 and generating a control signal CONsig to the data output block 603.

The data output block 603 includes an eleventh inverter INV11 for inverting the control signal CONsig, a second logic NAND gate NAND2 for performing a logic NAND operation to the data and the control signal CON_sig, a third logic NOR gate NOR3 for performing a logic NOR operation to the data and an output from the eleventh inverter INV11, a PMOS transistor P6 of which gate is coupled to the second logic NAND gate NAND2, and a NMOS transistor N8 of which gate is coupled to the third logic NOR gate NOR3, wherein a signal supplied on a node between the PMOS and NMOS transistors P6 and N8 is outputted as the data to the data pad.

Herein, in the data output block 603, an even number of inverters INV14 and INV15 or INV12 and INV13 are located between the second logic NAND gate NAND2 and the PMOS transistor P6 and between the third logic NOR gate NOR3 and the NMOS transistor N8.

Likewise, the digital signal output block 605 includes a sixteenth inverter INV16 for inverting the test enable signal TVM_EN, a third logic NAND gate NAND3 for performing a logic NAND operation to the digital signal VM_OUT, outputted from the buffering unit 215, and the test enable signal TVM_EN, a fourth logic NOR gate NOR4 for performing a logic NOR operation to the digital signal VM_OUT and an output from the sixteenth inverter INV16, a PMOS transistor P7 of which gate is coupled to the third logic NAND gate NAND3, and a NMOS transistor N9 of which gate is coupled to the fourth logic NOR gate NOR4, wherein a signal supplied on a node between the PMOS and NMOS transistors P7 and N9 is outputted as the digital signal VM_OUT to the data pad.

Similar to the data output block 603, the digital signal output block 605 includes an even number of inverters INV19 and INV20 or INV17 and INV18 located between the third logic NAND gate NAND3 and the PMOS transistor P7 and between the fourth logic NOR gate NOR4 and the NMOS transistor N9.

As above described, the multiplexing unit 217_C can deliver the transmitted digital signal VM_OUT or data into the data pad in response to the test enable signal TVM_EN and the data enable signal DOUT_EN. Herein, the data pad is coupled to the multiplexing unit 217_C. However, if the multiplexing unit 217 is coupled to an address pad or other functional pads instead of the data pad, the data output block 603 and the output controller 601 can be adjusted.

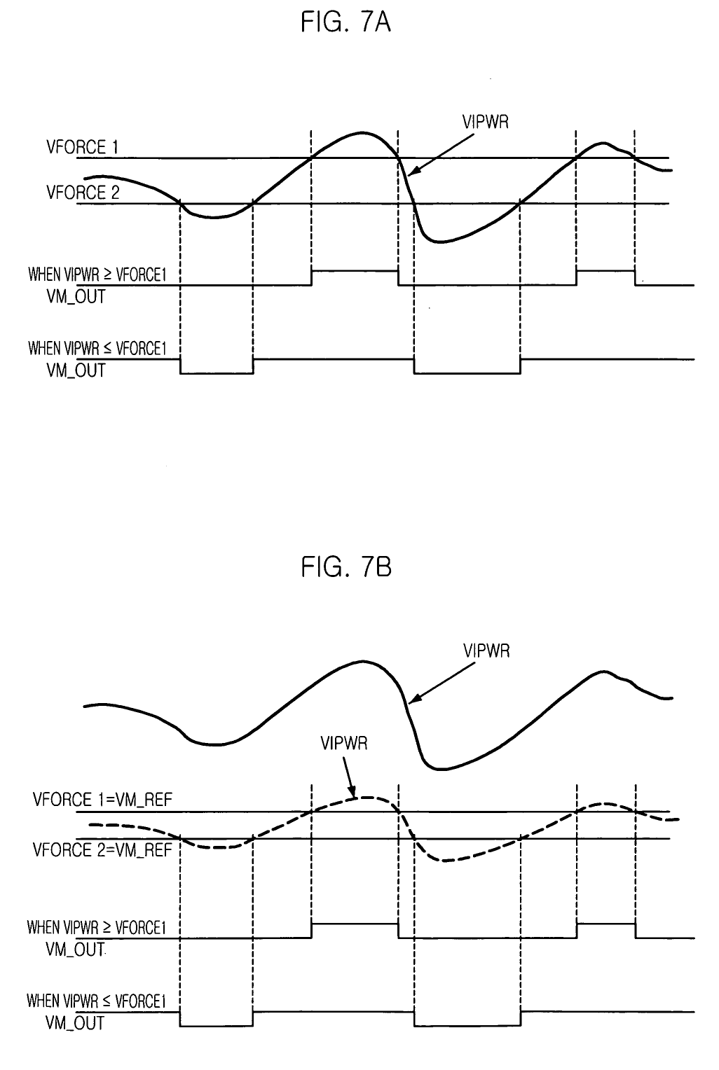

FIGS. 7A and 7B illustrate timing diagrams describing an operation of the internal power monitoring device shown in FIG. 2.

Referring to FIG. 7A, an internal power voltage VIPWR and two reference power voltages VFORCE1 and VFORCE2 are compared and the comparison result is converted into a digital signal VM_OUT by the comparator 209 include din the conversion device 201. The reference power voltages VFORCE1 and VFORCE2 can be selectively used according to inputted internal power voltage VIPWR. Herein, the internal power voltage VIPWR and the reference power voltages VFORCE1 and VFORCE2 are inputted to the first and second dividers 205 and 207 and divided by a predetermined ratio, before compared with each other.

The comparator 209 generates a logic high level signal if the internal power voltage VIPWR has a higher level than the reference power voltage VFORCE1 or VFORCE2; otherwise, if the internal power voltage VIPWR has a lower level than the reference power voltage VFORCE1 or VFORCE2, a digital signal having a logic low level is outputted.

Referring to FIG. 7B, an internal power voltage VIPWR is adjusted by the first divider 205, but a reference power voltage VFORCE1=VM_REF or VFORCE2=VM_REF is inputted to the comparator 209, not divided by the second divider 207. That is, FIG. 7B shows the conversion device 201 without the second divider 207.

The internal power voltage VIPWR (bold line) is divided by the first divider 205 and converted into a divided internal power voltage VIPWR (dot line). Herein, the reference power voltage VFORCE1 or VFORCE2 having a adjusted level VM_REF is inputted. The comparator 209 performs the same operation shown in FIG. 7A for generating the digital signal VM_OUT based on a comparison result.

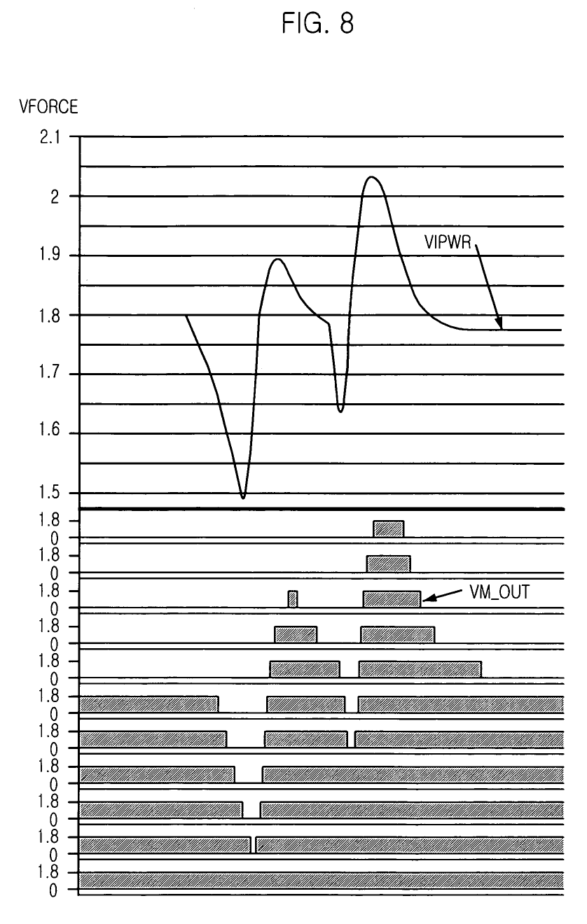

FIG. 8 illustrates a timing diagram depicting a digitalization of internal power voltage on a basis of plural reference power voltages.

As shown, the internal power voltage VIPWR is compared with plural reference power voltages. Herein, for performing a digitalization of the internal power voltage VIPWR, eleven reference power voltages having different levels in a range of 1.5 to 2.0 are used. The comparator 209 compares each of the eleven reference power voltages with the internal power voltage VIPWR to generate eleven digital signals based on each comparison result.

Transition edges of the eleven digital signals can show a change of the internal power voltage VIPWR roughly. If a level difference between reference power voltages is narrower and more reference power voltages are used than the above described case, the change of the internal power voltage VIPWR can be accurately sampled.

As above described, for overcoming limitations of conventional internal power voltage monitoring device, e.g., a difficulty for checking a level of internal power voltage after a semiconductor device is packaged and another difficulty for monitoring the internal power voltage of which level is narrowly or minutely swung, the present invention provides a digitalization of the internal power voltage and a transmission of the internal power voltage through a pad so that the internal power voltage can be monitored after a semiconductor device is packaged.

If a device for checking a level of internal power voltage is inside a chip of a semiconductor device, the device can support an operation for monitoring a level change of internal power voltage supplied on plural nodes or to plural inner functional blocks through plural pads.

Further, the present invention can support an operation for monitoring a level change of power voltage such as a power voltage (VDD) or control/data signal inputted from an external circuit instead of the internal power voltage generated by an inner functional block.

However, if the internal power voltage is neither changed widely nor affected dramatically by a noise, an internal power voltage monitoring device can be simplified.

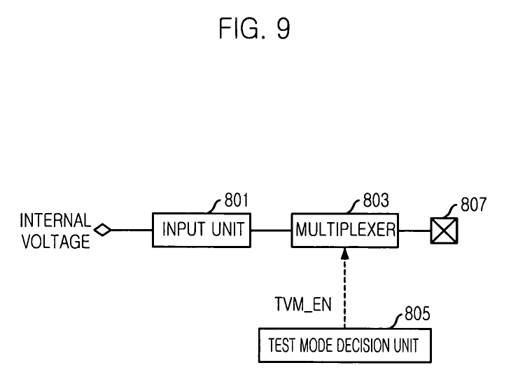

FIG. 9 illustrates a block diagram of an internal power voltage monitoring device in accordance with another embodiment of the present invention.

As shown, the internal power voltage monitoring device includes an input unit 801, a multiplexer 803, a test mode decision unit 805, and a predetermined pad 807.

The input unit 801 receives an internal power voltage and delivers the internal power voltage into the multiplexer 803. The multiplexer 803 outputs the internal power voltage to the predetermined pad 807 in response to a test enable signal TVM_EN. Herein, the multiplexer 803 can be substituted with multiplexing units 217_A to 217_C shown in FIGS. 6A to 6C. Also, the test mode decision unit 805 can be substituted with the test mode decision block 219 shown in FIGS. 2 and 4.

The predetermined pad 807 is a monitoring pad only used for checking a level of the internal power voltage. Thus, when a test is performed after a semiconductor device is packaged, the test can be formed by using the predetermined pad 807 without removing packaging materials for exposing an inside pad coupled to the internal power voltage.

As above described, when the internal power voltage is neither changed widely nor affected dramatically by a noise, it can be effective for monitoring a level of internal power voltage to only extract the internal power voltage to an external tester through the predetermined pad.

Though not shown in the Figures, the conversion device and the output device according to embodiments of the present invention can be changed based on characteristics of inputted signals or logic elements. For example, though the first and second dividers 205 and 207 include plural resistors, the first and second dividers can be formed by other active or passive elements such as transistors.

The present invention provides an apparatus and a method for monitoring an internal power voltage and generating a digital signal based on a monitored result after a semiconductor device is packaged. Also, the present invention provides an apparatus and a method for monitoring a narrow swing range of the internal power voltage accurately.

As above described, the present invention performs a digitalization to a difference between a reference power voltage and an internal power voltage by using a comparison unit and transmits a digitalized difference through a pad for monitoring a level of internal power voltage inside or outside of semiconductor device. Therefore, a narrow swing range of internal power voltage can be recognized effectively and accurately.

Further, the present invention provides an accurate analysis for checking a device performance and an effective guide for manufacturing or designing next-step semiconductor device. Though the semiconductor device according to the present invention is packaged, the internal power voltage can be outputted through a pin coupled to the pad. If necessary, the level of internal power voltage can be monitored by an external device.

While the present invention has been described with respect to the specific embodiments, it will be apparent to those skilled in the art that various changes and modifications may be made without departing from the spirit and scope of the invention as defined in the following claims.

What is claimed is:

1. An apparatus for monitoring an internal power voltage for use in a semiconductor device, comprising:
a conversion device for converting a difference between an internal power voltage and a reference power voltage into a digital signal; and
an output device for transmitting the digital signal in response to a test mode signal.

2. The apparatus of claim 1, wherein the conversion device includes:
a first divider for dividing a level of the internal power voltage by a predetermined ratio;
a second divider for dividing a level of the reference power voltage by the predetermined ratio; and
a comparison unit for comparing outputs of the first and second dividers to generate the digital signal.

3. The apparatus of claim 2, wherein the first divider includes at least two resistors for dividing the voltage level of the internal power voltage by a resistance ratio determined based on resistances of the resistors.

4. The apparatus of claim 2, wherein the first divider further includes a transmission gate for transmitting the internal power voltage in response to the test mode signal.

5. The apparatus of claim 2, wherein the internal power voltage includes plural inner power sources, supplied to different functional units included in the semiconductor device, for supporting operations of the functional units.

6. The apparatus of claim 5, wherein the first divider includes plural resistors and at least one transmission gate for dividing the inner power sources by different resistance ratios in response to the test mode signal.

7. The apparatus of claim 6, wherein the number of the transmission gates is equal to the number of the inner power sources, and the number of the resistors is larger than the number of the transmission gates.

8. The apparatus of claim 2, wherein the second divider is equal to the first divider in a view of its inner structure.

9. The apparatus of claim 1, wherein the conversion device further includes:
an input pad supplied with the reference power voltage; and
an electrostatic discharge unit coupled between the input pad and the second divider.

10. The apparatus of claim 1, wherein the output device includes:
a buffering unit for buffering the digital signal; and
a multiplexing unit for transmitting the digital signal to a pad in response to the test mode signal.

11. The apparatus of claim 10, wherein the multiplexing unit includes:
a first inverter for inverting the test mode signal;
a logic NAND gate for performing a logic NAND operation on the digital signal and the test mode signal;
a logic NOR gate for performing a logic NOR operation to the digital signal and an output from the first inverter;
a PMOS transistor having a gate coupled to the logic NAND gate; and
a NMOS transistor having a gate coupled to the logic NOR gate, wherein a signal supplied on a node between the PMOS and NMOS transistors is outputted as the data to the pad.

12. The apparatus of claim 11, wherein an even number of inverters is located between the logic NAND gate and the PMOS transistor and between the logic NOR gate and the NMOS transistor.

13. The apparatus of claim 9, wherein the pad includes an address pad for address input/output, a data pad for data input/output, and a monitoring pad which is unfit for data access.

14. The apparatus of claim 10, wherein the multiplexing unit further transmits data in response to a data output enable signal during a data access.

15. The apparatus of claim 10, wherein the multiplexing unit includes:
a data output block for delivering data to the pad;
a digital signal output block for delivering the digital signal to the pad in response to the test mode signal; and
a output controller for controlling the data output block in response to the test mode signal and a data output enable signal.

16. The apparatus of claim 15, wherein the output controller includes:
an inverter for inverting the data output enable signal; and
a logic NOR gate for performing a logic NOR operation to the test mode signal and output of the inverter.

17. The apparatus of claim 15, wherein the data output block includes:
a first inverter for inverting an output from the output controller;
a logic NAND gate for performing a logic NAND operation on the data and the output from the output controller;
a logic NOR gate for performing a logic NOR operation on the data and an output from the first inverter;
a PMOS transistor having a gate coupled to the logic NAND gate; and
a NMOS transistor having a gate coupled to the logic NOR gate, wherein a signal supplied on a node between the PMOS and NMOS transistors is outputted as the data to the predetermined pad.

18. The apparatus of claim 17, wherein an even number of inverters is located between the logic NAND gate and the PMOS transistor and between the logic NOR gate and the NMOS transistor.

19. The apparatus of claim 15, wherein the digital signal output block includes:
a first inverter for inverting the test mode signal;
a logic NAND gate for performing a logic NAND operation on the digital signal and the test mode signal;
a logic NOR gate for performing a logic NOR operation on the digital signal and an output from the first inverter;
a PMOS transistor having a gate coupled to the logic NAND gate; and
a NMOS transistor having a gate coupled to the logic NOR gate, wherein a signal supplied on a node between the PMOS and NMOS transistors is outputted as the digital signal to the predetermined pad.

20. The apparatus of claim 19, wherein an even number of inverters is located between the logic NAND gate and the PMOS transistor and between the logic NOR gate and the NMOS transistor.

21. An apparatus for monitoring an internal power voltage used inside a semiconductor memory device, comprising:
a voltage input device for sensing a level of a power voltage to generate a signal corresponding to the sensed level; and
an output device for transmitting the signal in response to a test mode signal.

22. The apparatus of claim 21, wherein the output device includes:
a first inverter for inverting the test mode signal;
a logic NAND gate for performing a logic NAND operation on the signal and the test mode signal;
a logic NOR gate for performing a logic NOR operation on the signal and an output from the first inverter;
a PMOS transistor having a gate coupled to the logic NAND gate; and
a NMOS transistor having a gate coupled to the logic NOR gate, wherein a signal supplied on a node between the PMOS and NMOS transistors is outputted as the data to a pad.

23. The apparatus of claim 22, wherein an even number of inverters is located between the logic NAND gate and the PMOS transistor and between the logic NOR gate and the NMOS transistor.

24. The apparatus of claim 21, further comprising a data input device for delivering data to the output device in response to the test mode signal.

25. The apparatus of claim 24, wherein the signal is outputted through at least one pad including an address pad for address input/output, a data pad for data input/output, and a monitoring pad which is unfit for data access.

26. The apparatus of claim 25, wherein the output device includes:
a data output block for delivering the data to the at least one pad;
a signal output block for delivering the signal to the at least one pad in response to the test mode signal; and
a output controller for controlling the data output block in response to the test mode signal and a data output enable signal.

27. The apparatus of claim 26, wherein the output controller includes:
an inverter for inverting the data output enable signal; and
a logic NOR gate for performing a logic NOR operation on the test mode signal and said output of the inverter.

28. The apparatus of claim 26, wherein the data output block includes:
a first inverter for inverting an output from the output controller;
a logic NAND gate for performing a logic NAND operation on the data and the output from the output controller;
a logic NOR gate for performing a logic NOR operation on the data and an output from the first inverter;
a PMOS transistor having a gate coupled to the logic NAND gate; and
a NMOS transistor having a gate coupled to the logic NOR gate, wherein a second signal supplied on a node between the PMOS and NMOS transistors is outputted as the data to the at least one pad.

29. The apparatus of claim 28, wherein an even number of inverters is located between the logic NAND gate and the PMOS transistor and between the logic NOR gate and the NMOS transistor.

30. The apparatus of claim 26, wherein the signal output block includes:
a first inverter for inverting the test mode signal;
a logic NAND gate for performing a logic NAND operation on the digital signal and the test mode signal;
a logic NOR gate for performing a logic NOR operation on the digital signal and an output from the first inverter;
a PMOS transistor having a gate coupled to the logic NAND gate; and
a NMOS transistor having a gate coupled to the logic NOR gate, wherein a second signal supplied on a node between the PMOS and NMOS transistors is outputted as the signal to the predetermined pad.

31. The apparatus of claim 31, wherein an even number of inverters is located between the logic NAND gate and the PMOS transistor and between the logic NOR gate and the NMOS transistor.

32. A method for monitoring an internal power voltage for use in a semiconductor device, comprising:
converting a difference between an internal power voltage and a reference power voltage into a digital signal; and
transmitting the digital signal in response to a test mode signal.

33. The method of claim 32, wherein the converting the difference includes:
dividing a level of the internal power voltage by a predetermined ratio;
dividing a level of the reference power voltage by the predetermined ratio; and
comparing outputs of the first and second dividers to generate the digital signal

34. The method of claim 32, wherein the transmitting the digital signal includes:
buffering the digital signal; and
outputting the digital signal to a pad in response to the test mode signal.

35. The method of claim 34, wherein the transmitting the digital signal further includes outputting data in response to the test mode signal and a data output enable signal during a data access.

36. A method for monitoring an internal power voltage used inside a semiconductor memory device, comprising:
sensing a level of a power voltage to generate a signal corresponding to the sensed level; and
transmitting the signal in response to a test mode signal.

37. The method of claim 36, wherein the transmitting the signal includes:
buffering the signal; and
outputting the signal to a pad in response to the test mode signal.

38. The method of claim 37, wherein the transmitting the signal further includes outputting data in response to the test mode signal and a data output enable signal during a data access.
